(19) United States
(12) Patent Application Publication
(10) Pub. No.: US 2026/0136951 A1
(43) Pub. Date: May 14, 2026

(54) LEAD FRAME

(71) Applicant: JCET Group Co., LTD., Jiangyin (CN)

(72) Inventors: Tianzheng LIAO, Jiangyin (CN); Dan ZHAO, Jiangyin (CN); Na ZHOU, Jiangyin (CN); Yi LIU, Jiangyin (CN)

(21) Appl. No.: 19/384,487

(22) Filed: Nov. 10, 2025

(30) Foreign Application Priority Data
Nov. 12, 2024 (CN) 202411607283.6

(51) Int. Cl. H01L 23/495

(52) U.S. Cl. CPC H10W 70/438; H10W 70/424

(57) ABSTRACT

A lead frame is provided. The lead frame includes frame units each including leads and a frame dambar arranged between adjacent frame units of the frame units. The frame dambar includes a base body and a microstructure, the base body is connected with the leads, and the microstructure is arranged on the base body. A configuration of the microstructure is associated with a width of the base body to reduce or eliminate copper chips generated during a first cutting operation with a predetermined width.

### CROSS-REFERENCE TO RELATED APPLICATIONS

This application claims the benefit of priority to Chinese Application No. 202411607283.6, filed November 12, 2024, which is incorporated herein by reference in its entirety.

### TECHNICAL FIELD

The present disclosure relates to the field of semiconductor package, and particularly relates to a lead frame.

### BACKGROUND

Wettable Flank Quad Flat No-leads Package (QFN) products can achieve soldering on the side of leads, and compared to traditional QFN products, they have high welding ability due to their wettable flanks and are widely used in automotive, military, and medical equipment and other fields.

Currently, there are two common wettable flank QFN processes in the industry, one process is lead dimple/cavity, and the other is lead step cutting; in the lead dimple/cavity package structure, burrs tend to exist at the dimple locations, thus the step cutting technology solution is more widely used.

### SUMMARY

The technical problem to be solved by the present disclosure is to provide a lead frame, which can reduce or even avoid the occurrence of burr abnormalities in package products using step cutting, thereby improving the yield of package products.

In order to solve the above problems, an embodiment of the present disclosure provides a lead frame, including: a frame unit, the frame unit including leads; and a frame dambar arranged between the adjacent frame units, the frame dambar including a base body and a microstructure, the base body being connected with the leads, and the microstructure being arranged on the base body, and the configuration of the microstructure being associated with the width of the base body to reduce or even eliminate the amount of copper chips generated during the first cutting operation with a predetermined width.

In one embodiment, the base body has a first width, the first width is less than the predetermined width and greater than or equal to two-thirds of the predetermined width, and the microstructure is at least one of a through-hole running through the base body or a groove recessed into the base body, the width of the through-hole or groove being less than the first width.

In one embodiment, the through-hole or groove is arranged between the leads of the two adjacent frame units.

In one embodiment, the cross-sectional area of the through-hole or groove is 1/4 to 1/3 of the cross-sectional area of the lead.

In one embodiment, the frame dambars include a plurality of the through-holes or grooves, and the plurality of through-holes or grooves are uniformly distributed in the extension direction of the base body.

In one embodiment, the through-hole or groove is arranged on the centerline of the base body.

In one embodiment, the base body has a second width, the second width is less than two-thirds of the predetermined width and greater than one-third of the predetermined width, and the microstructure is a protruding strip arranged on the surface of the base body, and the protruding strip extends along the extension direction of the base body, the width of the protruding strip is less than the second width.

In one embodiment, the width of the protruding strip is 1/3 to 1/2 of the second width.

In one embodiment, the surface of the protruding strip is flush with the surface of the lead, or the surface of the protruding strip is lower than the surface of the lead.

In one embodiment, the protruding strip is arranged on the centerline of the base body.

In one embodiment, the surface of the base body is lower than the surface of the leads.

In one embodiment, the width of the area where the base body is connected with the leads is greater than the width of the area where it is not connected with the leads.

### BRIEF DESCRIPTION OF THE DRAWINGS

In order to explain the technical solutions in the embodiments of the present disclosure, the accompanying drawings required for the description of the embodiments will be briefly introduced below. It is obvious that the accompanying drawings described below are only some embodiments of the present disclosure, for those skilled in the art, other accompanying drawings can be obtained according to these accompanying drawings without inventive effort.

FIG. 1 is a bottom view schematic diagram of the lead frame provided by the first embodiment of the present disclosure;

FIG. 2 is a cross-sectional schematic diagram along line A-A1 in FIG. 1;

FIG. 3 is a cross-sectional schematic diagram along line B-B1 in FIG. 1;

FIG. 4 is a cross-sectional schematic diagram of the lead frame provided by the second embodiment of the present disclosure along line A-A1 in FIG. 1;

FIG. 5 is a bottom view of the lead frame provided by the third embodiment of the present disclosure;

FIG. 6 is a cross-sectional schematic diagram along line A-A1 in FIG. 5; and

FIG. 7 is a cross-sectional schematic diagram along line B-B1 in FIG. 5.

### DETAILED DESCRIPTION

As described in the background, package products using step cutting tend to have burr abnormalities, and the reliability of the package products cannot meet requirements.

The step cutting process is typically divided into two cuttings, during the first cutting of the molding structure, some leads and frame dambars are removed, and after the first cutting, electroplating is performed, and after the electroplating, then the second cutting is performed to form an independent package structure. In the cutting process, in order to save costs, diamond is typically used as the dicing blade to reduce the wear of the dicing blade.

There is a phenomenon of copper coating on the cutting edge during the cutting process, as the wear of the dicing blade decreases, the cutting force of the dicing blade also decreases, making it difficult to expel copper chips, and these chips stack and extend in the dicing lane; during electroplating, the stacking and extension areas will also be electroplated; during the second cutting, the stacked copper chips are forced to extend under the pressure of the dicing blade, forming burrs at the edges of the steps, causing abnormal burrs in the package structure and affecting product yield.

Currently, the frame dambar of package products using step cutting has width less than or equal to 0.2mm, and has a high and stable yield, however, products with frame dambar width greater than 0.2mm and with product thickness greater than 2mm have a small amount of burr abnormalities due to the effect of design and process factors, and the yield of package products cannot meet the requirements.

In view of this, the embodiments of the present disclosure provide a lead frame that can reduce or even avoid the occurrence of burr abnormalities in package products using step cutting, thereby improving the yield of package products.

In the lead frame provided by the embodiments of the present disclosure, the frame dambar includes a base body and a microstructure, the configuration of the microstructure is related to the width of the base body, and the two are arranged in association to ensure the strength of the frame dambar while reducing the volume of the frame dambar located within the dicing lane with a predetermined width. Wherein, reducing the volume of the frame dambar within the dicing lane can reduce or even eliminate the amount of copper chips generated during the first cutting in the step cutting process, thereby reducing or even avoiding the occurrence of burr abnormalities in package products using step cutting, thereby improving the yield of package products.

The specific implementation of the lead frame provided by the present disclosure will be described in detail below with reference to the accompanying drawings.

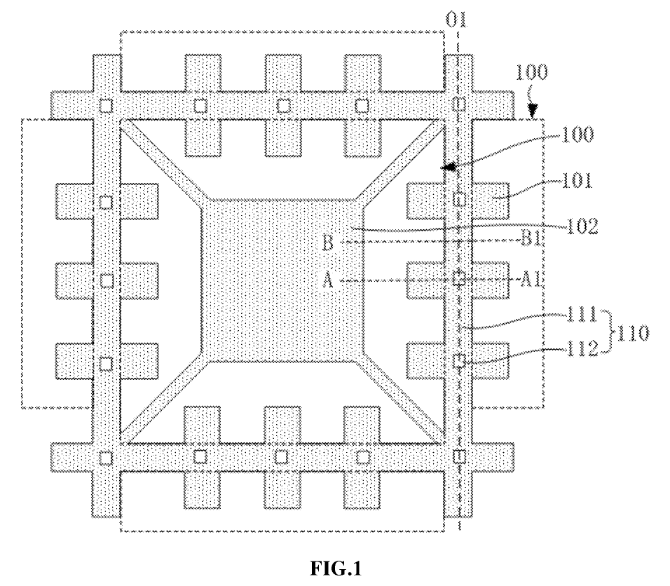

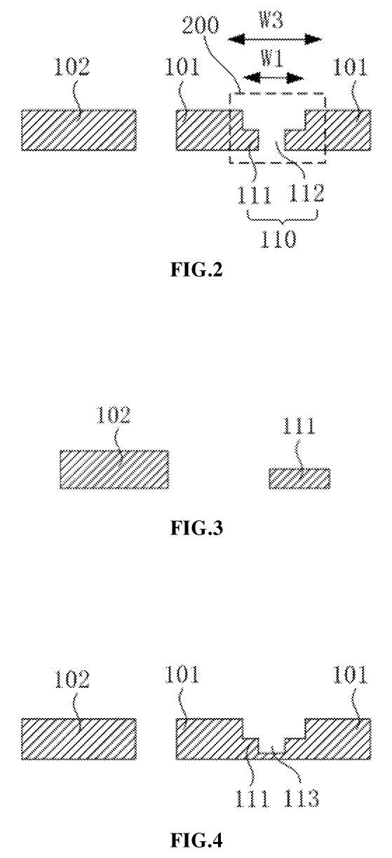

Referring to FIGS. 1 to 3, wherein FIG. 1 is a bottom view schematic diagram of the lead frame provided by the first embodiment of the present disclosure, FIG. 2 is a cross-sectional schematic diagram along line A-A1 in FIG. 1, FIG. 3 is a cross-sectional schematic diagram along line B-B1 in FIG. 1, the lead frame includes: a frame unit 100, the frame unit 100 including leads 101; a frame dambar 110 arranged between the adjacent frame units 100, the frame dambar 110 includes a base body 111 and a microstructure, the base body 111 being connected with the leads 101, and the microstructure being arranged on the base body 111; furthermore, and the configuration of the microstructure is associated with the width of the base body 111 to reduce the volume of the frame dambar 110 within the dicing lane 200 of a predetermined width W3 and to increase the strength of the frame dambar 110.

The lead frame includes a plurality of frame units 100, each frame unit 100 including a base island 102 and leads 101 arranged around the base island 102, the base islands 102 and leads 101 of adjacent frame units 100 are interconnected by the frame dambars 110. In FIG. 1, only one complete frame unit 100 is illustrated for illustrative purposes, and for the other frame units 100 around this frame unit 100, only leads 101 are illustrated.

In the lead frame provided by the present disclosure, the frame dambar 110 includes a base body 111 and a microstructure; the configuration of the microstructure is related to the width of the base body 111, and the two are arranged in association to ensure the strength of the frame dambar 110 while reducing the volume of the frame dambar 110 located within the dicing lane 200 with a predetermined width W3.

Wherein, reducing the volume of the frame dambar 110 within the dicing lane 200 can reduce or even eliminate the amount of copper chips generated during the first cutting in the step cutting process, thereby reducing or even avoiding the occurrence of burr abnormalities in package products using step cutting, thereby improving the yield of package products.

The dicing lane 200 is arranged between the adjacent frame units 100, and the width of the dicing lane is greater than or equal to the gap between the adjacent frame units 100. In the step cutting process, the first cutting is performed along the dicing lane 200, the predetermined width of the first cutting W3 is greater than the width of the dicing lane, consequently, the end of the lead 101 of the frame unit 100 connected with the frame dambar 110 is also partially diced, thereby enabling the formation of a step at the lead 101. The dicing lane is illustrated with dashed lines in FIG. 2. A second cutting is performed subsequently along the dicing lane 200 to form an independent package structure, and the cutting width of the second cutting is the width of the dicing lane.

The area where the dicing lane 200 is located covers the area where the frame dambar 110 is located, and the area of the region where the dicing lane 200 is located is greater than the area of the region where the frame dambar 110 is located, so as to ensure that the frame dambar 110 can be completely removed during the second cutting in the step cutting process.

The base body 111 is arranged between the adjacent frame units 100 and the base body 111 extends along the gap between the adjacent frame units 100. In the present embodiment, the base body 111 has a first width W1, the first width W1 is less than or equal to the width of the dicing lane, and the first width W1 is less than the predetermined width W3 and greater than or equal to two-thirds of the predetermined width W3, and the microstructure is at least one of through-holes 112 running through the base body 111 or grooves 113 recessed into the base body 111 (referring to FIG. 4), with the width of the through-hole 112 or groove 113 being less than the first width W1. The first width W1 of the base body 111 refers to the width of the base body 111 in a direction perpendicular to the extension direction of the base body 111.

The first width W1 of the base body 111 is less than or equal to the width of the dicing lane, i.e., the base body 111 is entirely located within the dicing lane 200, which can ensure that the frame dambar 110 is completely removed during the step cutting process; The first width W1 of the base body 111 is greater than or equal to two-thirds of the predetermined width W3, which can ensure the strength of the frame dambar 110, thereby ensuring the supporting strength of the frame dambar 110 for the leads 101 and the base island 102.

In the present embodiment, the microstructure is a through-hole 112 running through the base body 111, and the width of the through-hole 112 is less than the first width W1. Compared to a structure where the frame dambar 110 is entirely formed by the base body 111, the present embodiment reduces the volume of the frame dambar 110 through the arrangement of the through-hole 112, thereby reducing or even eliminating the amount of copper chips generated during the first cutting in the step cutting process. The cross-sectional shape of the through-hole 112 includes but is not limited to circular, elliptical, rectangular, triangular, polygonal, and etc.

In the second embodiment, referring to FIG. 4, which is a cross-sectional schematic diagram of the lead frame provided by the second embodiment of the present disclosure along line A-A1 in FIG. 1, the microstructure is a groove 113 recessed into the base body 111, with the width of groove 113 being less than the first width W1. Compared to a structure where the frame dambar 110 is entirely formed by the base body 111, the present embodiment reduces the volume of the frame dambar 110 through the arrangement of the groove 113, thereby reducing or even eliminating the amount of copper chips generated during the first cutting step in the step cutting process; furthermore, compared to the arrangement with through-hole 112, the present embodiment can further enhance the strength of the frame dambar 110 through the arrangement of the groove 113. Wherein, the cross-sectional shape of the groove 113 includes but is not limited to circular, elliptical, rectangular, triangular, polygonal, and etc.

In the above embodiment, the through-hole 112 or the groove 113 is provided on the base body 111, in other embodiments, both the through-hole 112 and the groove 113 may be provided on the base body 111; the through-hole 112 and the groove 113 are arranged at intervals, thereby reducing the volume of the frame dambar 110 while further ensuring the strength of the frame dambar 110.

In some embodiments, the frame dambar 110 includes a plurality of through-holes 112 or grooves 113, in the extension direction of the base body 111, the plurality of through-holes 112 or grooves 113 are uniformly distributed to ensure the strength of the frame dambar 110.

In some embodiments, the through-holes 112 or grooves 113 are arranged between the leads 101 of the two adjacent frame units 100, for example, as shown in FIG. 1, the through-holes 112 are arranged between the leads 101 of the two adjacent frame units 100. Arranging the through-holes 112 or grooves 113 between the leads 101 of the two adjacent frame units 100 reduces the frame dambars 110 between the leads 101, thereby reducing the amount of copper chips generated at the leads 101 in the step cutting process; consequently, even if burrs are generated during the step cutting process, this burrs will not exist at the leads 101, thereby avoiding burrs connecting with adjacent leads 101. Wherein, adjacent leads 101 include adjacent leads 101 of the same frame unit 100 or adjacent leads 101 of different frame units 100.

In other embodiments, the through-holes 112 or grooves 113 may be not arranged between the leads 101 of the two adjacent frame units 100, but rather located in areas of the base body 111 not corresponding to the leads 101; alternatively, a part of the through-holes 112 or grooves 113 are arranged between the leads 101 of the two adjacent frame units 100, while another part of the through-holes 112 or grooves 113 are located in the areas of the base body 111 not corresponding to the leads 101.

In some embodiments, the cross-sectional area of the through-hole 112 or groove 113 is 1/4 to 1/3 of the cross-sectional area of the lead 101. For example, as shown in FIG. 1, the cross-sectional area of the through-hole 112 is 1/4 to 1/3 of the cross-sectional area of the lead 101. If the cross-sectional area of the through-hole 112 or the groove 113 is too large, it will reduce the strength of the frame dambar 110; if the cross-sectional area of the through-hole 112 or the groove 113 is too small, it cannot effectively improve the amount of copper chips; when the cross-sectional area of the through-hole 112 or the groove 113 is 1/4 to 1/3 of the cross-sectional area of the lead 101, it can balance the strength of the frame dambar 110 and reduce the amount of copper chips.

In some embodiments, the through-hole 112 or groove 113 is arranged on the centerline O1 of the base body 111, the centerline O1 extends along the extension direction of the base body 111, for example, as shown in FIG. 1, the through-hole 112 is arranged on the centerline O1 of the base body 111. This arrangement enables that the through-hole 112 or groove 113 are uniform distributed between the frame units 100, avoiding non-uniformity of cutting for adjacent frame units 100 during the step cutting process and enhancing the consistency of the subsequently formed package structure.

In some embodiments, the surface of the base body 111 is lower than the surface of the leads 101, which can further reduce the volume of the frame dambars 110. For example, if the base body 111 is obtained by half etching the lead frame base body material, the thickness of the base body 111 is half of the thickness of the leads 101, and the through-holes 112 or grooves 113 are arranged in the half etched area.

In some embodiments, the width of the area where the base body 111 is connected with the leads 101 is greater than the width of the area where it is not connected with the leads 101, which further enhances the supporting strength of the frame dambar 110 for the leads 101 and reducing the volume of the frame dambar 110. As shown in FIG. 2, it is a cross-sectional schematic diagram of the area where the base body 111 is connected with the lead 101, and as shown in FIG. 3, it is a cross-sectional schematic diagram of the area where the base body 111 is not connected with the lead 101, the width of the area where the base body 111 is connected with the lead 101 is greater than the width of the area where it is not connected with the lead 101.

In the above embodiment, the base body 111 has a first width W1, and the microstructure is at least one of a through-hole 112 running through the base body 111 or a groove 113 recessed into the base body 111, in other embodiments, the base body 111 has a second width W2, and the microstructure is a protruding strip 114 arranged on the surface of the base body 111.

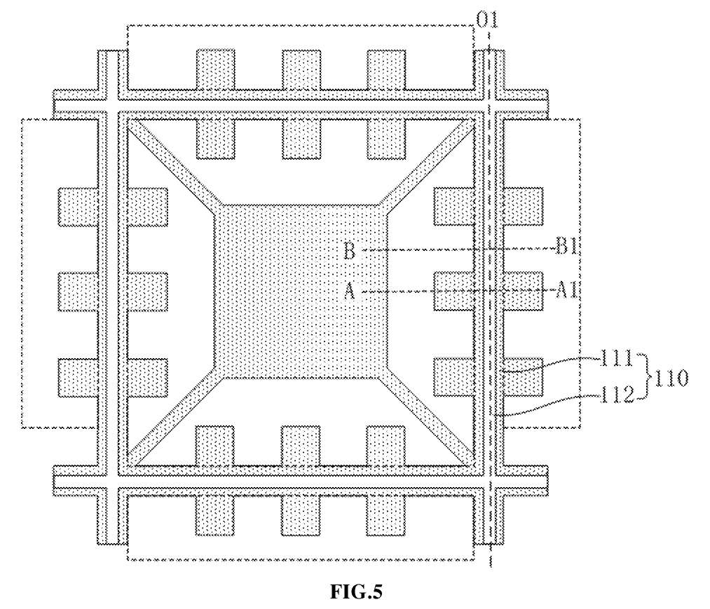

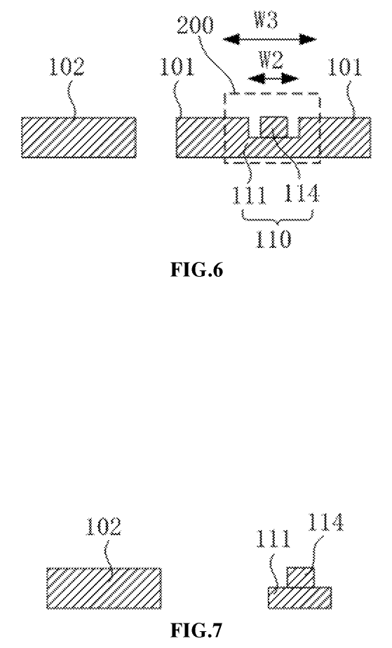

Referring to FIGS. 5 to 7, wherein FIG. 5 is a bottom view of the lead frame provided by the third embodiment of the present disclosure, FIG. 6 is a cross-sectional schematic diagram along line A-A1 in FIG. 5, FIG. 7 is a cross-sectional schematic diagram along line B-B1 in FIG. 5; in this embodiment, the base body 111 has a second width W2, the second width W2 is less than or equal to the width of the dicing lane, the second width W2 is less than two-thirds of the predetermined width W3 and greater than one-third of the predetermined width W3, and the microstructure is a protruding strip 114 arranged on the surface of the base body 111, and the protruding strip 114 extending along the extension direction of the base body 111, the width of the protruding strip 114 is less than the second width W2. The second width W2 of the base body 111 refers to the width of the base body 111 in a direction perpendicular to the extension direction of the base body 111, and the width of the protruding strip 114 refers to the width of the protruding strip 114 in a direction perpendicular to the extension direction of the base body 111.

On the one hand, the second width W2 of the base body 111 is less than or equal to the width of the dicing lane, such that the base body 111 is entirely located within the dicing lane 200; on the other hand, the second width W2 is less than two-thirds of the predetermined width W3, the arrangement of the second width W2 in the present embodiment can reduce the volume of the frame dambar 110, thereby decreasing or even eliminating the amount of copper chips generated during the first cutting step in the step cutting process. Furthermore, the protruding strip 114 is arranged on the surface of the base body 111, which can enhance the strength of the frame dambar 110, thereby ensuring the supporting strength of the frame connecting rib 110 for the lead 101. The dicing lane 200 is illustrated with dashed lines in FIG. 6.

In some embodiments, the width of the protruding strip 114 is 1/3 to 1/2 of the second width W2. If the width of the protruding strip 114 is too small, it will reduce the strength of the frame dambar 110; if the width of the protruding strip 114 is too large, it fails to effectively improve the amount of copper chips; if the width of the protruding strip 114 is 1/3 to 1/2 of the second width W2, it is able to both ensure the strength of the frame dambar 110 and reduce the amount of copper chips.

In some embodiments, the protruding strip 114 is arranged on the centerline O1 of the base body 111, the centerline O1 extends in the extension direction of the base body 111. This arrangement ensures that the protruding strip 114 is uniform distributed between the frame units 100, avoiding non-uniformity of cutting for adjacent frame units 100 during the step cutting process and enhancing the consistency of the subsequently formed package structure.

In some embodiments, the surface of the base body 111 is lower than the surface of the leads 101, which can further reduce the volume of the frame dambars 110. For example, if the base body 111 is obtained by half etching the lead frame base body material, the thickness of the base body 111 is half of the thickness of the leads 101, and the protruding strip 114 is arranged within the half etched area, thereby enhancing the strength of the frame dambars 110.

In some embodiments, the surface of the protruding strip 114 is flush with the surface of the lead 101, or the surface of the protruding strip 114 is lower than the surface of the lead 101, which provides sufficient supporting strength while avoiding significant impact on the structure of the lead frame. For example, as shown in FIG. 5, the surface of the protruding strip 114 is flush with the surface of the lead 101. In some embodiments, when forming the frame dambar 110 by half etching the lead frame base body, only the area between the protruding strip 114 and the lead 101 is half etched, so that the surface of the protrusion strip 114 is flush with the surface of the lead 101.

The lead frame provided by the embodiments of the present disclosure can reduce or even avoid the occurrence of burr abnormalities in package products using step cutting by arranging the configuration of the microstructure in association with the width of the base body, thereby improving the yield of package products.

It should be noted that the terms “include” and “have” and their variations referred to in the document of the present disclosure are intended to cover non-exclusive inclusions. The terms such as “first,” “second,” etc., are used to distinguish similar objects and are not necessarily used to describe a specific order or sequence, and it is appreciated that unless otherwise indicated in the context clearly, the data used in this way can be interchanged in appropriate circumstances. The term “one or more” is at least partially dependent on the context and may be used to describe features, structures, or characteristics in a singular sense or in a plural sense. The term “based on” may be understood as not necessarily intended to express a set of exclusive factors, but may alternatively, also at least partially dependent on the context, permit the existence of other factors that may not be explicitly described. In addition, the embodiments of the present disclosure and features in the embodiments may be combined with each other without conflict. Additionally, in the above explanation, descriptions of well-known components and technologies have been omitted to avoid unnecessary confusion of the concepts of the present disclosure. In the above embodiments, each embodiment focuses on illustrating differences from other embodiments, and the same/similar portions between the embodiments can be referred to each other.

The above is only the preferred embodiments of the present disclosure, it should be noted that those skilled in the art may also make several improvements and refinements without departing from the principles of the present disclosure, these improvements and refinements should also be considered as the scope of protection of the present disclosure.

What is claimed is:

1. A lead frame, comprising:
frame units, each comprising leads; and
a frame dambar arranged between two adjacent frame units of the frame units,
wherein the frame dambar comprises a base body and a microstructure, the base body is connected with the leads, and the microstructure is arranged on the base body; and
wherein a configuration of the microstructure is associated with a width of the base body to reduce or eliminate copper chips generated during a first cutting operation with a predetermined width.

2. The lead frame according to claim 1,
wherein the base body has a first width, and the first width of the base body is less than the predetermined width and greater than or equal to two-thirds of the predetermined width; and
wherein the microstructure comprises at least one of a through-hole extending through the base body or a groove recessed into the base body, and a width of the through-hole or the groove is less than the first width.

3. The lead frame according to claim 2, wherein the through-hole or the groove is arranged between the leads of the two adjacent frame units.

4. The lead frame according to claim 2, wherein the through-hole or the groove is arranged in a region of the base body not corresponding to the leads.

5. The lead frame according to claim 2, wherein a cross-sectional area of the through-hole or the groove is 1/4 to 1/3 of that of the leads.

6. The lead frame according to claim 2, wherein the frame dambars comprise a plurality of the through-holes or the grooves, and the plurality of through-holes or the grooves are uniformly distributed in an extension direction of the base body.

7. The lead frame according to claim 2, wherein the through-hole or the groove is arranged on a centerline of the base body.

8. The lead frame according to claim 1,
wherein the base body has a second width, and the second width is less than two-thirds of the predetermined width and greater than one-third of the predetermined width; and
wherein the microstructure is a protruding strip arranged on a surface of the base body, and the protruding strip extends along an extension direction of the base body, wherein a width of the protruding strip is less than the second width.

9. The lead frame according to claim 8, wherein the width of the protruding strip is 1/3 to 1/2 of the second width.

10. The lead frame according to claim 8, wherein a surface of the protruding strip is flush with a surface of one of the leads, or the surface of the protruding strip is lower than the surface of the one of the leads.

11. The lead frame according to claim 8, wherein the protruding strip is arranged on a centerline of the base body.

12. The lead frame according to claim 1, wherein a surface of the base body is lower than a surface of one of the leads.

13. The lead frame according to claim 12, wherein a width of an area where the base body is connected with the leads is greater than a width of an area where the base body is not connected with the leads.

14. The lead frame according to claim 2,
wherein the base body has a second width, and the second width is less than two-thirds of the predetermined width and greater than one-third of the predetermined width, and
wherein the microstructure is a protruding strip arranged on a surface of the base body, and the protruding strip extends along an extension direction of the base body, wherein a width of the protruding strip is less than the second width.

15. The lead frame according to claim 14, wherein the width of the protruding strip is 1/3 to 1/2 of the second width.

16. The lead frame according to claim 14, wherein a surface of the protruding strip is flush with a surface of one of the leads, or the surface of the protruding strip is lower than the surface of the one of the leads.

17. The lead frame according to claim 14, wherein the protruding strip is arranged on a centerline of the base body.

18. A semiconductor package, comprising:
a lead frame, wherein the lead frame comprises:
frame units, each comprising leads; and
a frame dambar arranged between two adjacent frame units of the frame units,
wherein the frame dambar comprises a base body and a microstructure, the base body is connected with the leads, and the microstructure is arranged on the base body; and
wherein a configuration of the microstructure is associated with a width of the base body to reduce or eliminate copper chips generated during a first cutting operation with a predetermined width.

19. The semiconductor package according to claim 18,
wherein the base body has a first width, and the first width of the base body is less than the predetermined width and greater than or equal to two-thirds of the predetermined width; and
wherein the microstructure comprises at least one of a through-hole extending through the base body or a groove recessed into the base body, and a width of the through-hole or the groove is less than the first width.

20. The semiconductor package according to claim 18,
wherein the base body has a second width, and the second width is less than two-thirds of the predetermined width and greater than one-third of the predetermined width; and
wherein the microstructure is a protruding strip arranged on a surface of the base body, and the protruding strip extends along an extension direction of the base body, wherein a width of the protruding strip is less than the second width.
